(19) United States
(12) Patent Application Publication
(10) Pub. No.: US 2012/0275110 A1
(43) Pub. Date: Nov. 1, 2012

(54) NOTEBOOK COMPUTER POWER SUPPLY

(75) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/158,470

(22) Filed: Jun. 13, 2011

(30) Foreign Application Priority Data
Apr. 28, 2011 (CN) 201110108674.X

(51) Int. Cl. H05K 5/02

(52) U.S. Cl. 361/679.55

(57) ABSTRACT

A notebook computer includes a main body, a battery, and a power adaptor. The main body defines a mounting slot and includes a connector exposed in the mounting slot. Either the battery or the power adaptor may be mounted in the mounting slot. The battery defines a socket for electrical engagement with the connector of the main body. The power adaptor also defines a socket to engage with the connector, and a power source interface connected to an alternating power source.

### BACKGROUND

1. Technical Field

The present disclosure relates to batteries, particularly to a battery for a notebook computer.

2. Description of Related Art

Notebook computers can be powered through a battery or a power adaptor connected to an alternating current (AC) power source. When the notebook computer is used in an office or home, where the AC power source is conveniently available, supplying power through the power adaptor is more popular than using the battery, in order to prolong the life of the battery. The power adaptor is large and heavy, and usually requires two cables, respectively connecting the AC power source to the power adaptor and the power adaptor to the notebook computer. Space is required for the power adaptor and the two cables and the lifestyle of the user would be improved by a better means of powering a notebook computer.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a notebook computer, which includes a main body, a battery, and a power adaptor.

FIG. 2 is an enlarged view of the battery and the power adaptor of FIG. 1, but shown in a different perspective.

FIG. 3 is an assembled view of the main body and the battery of FIG. 1.

FIG. 4 is an assembled view of the main body and the power adaptor of FIG. 1.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

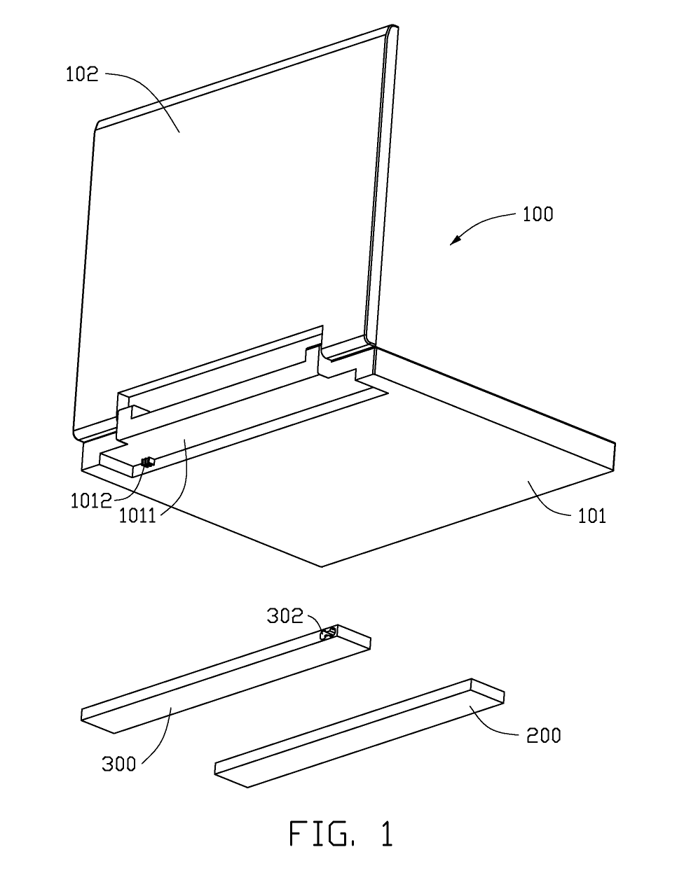

Referring to FIG. 1, an exemplary embodiment of a notebook computer includes a main body 100, a battery 200, and a power adaptor 300.

The main body 100 includes a base 101, and a cover 102 pivotably mounted to the base 101. The base 101 defines a mounting slot 1011 in the base 101. The main body 100 includes a connector 1012 exposed through and protruding from a side wall of the mounting slot 1011.

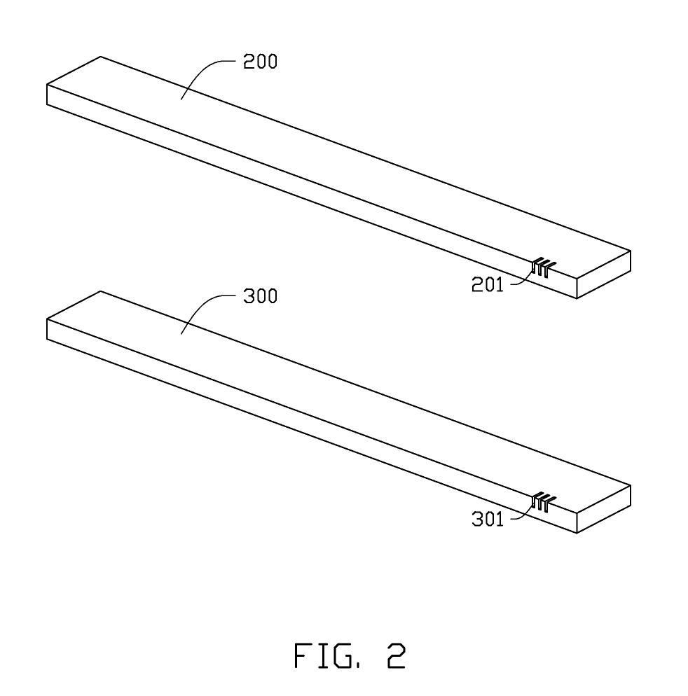

Referring to FIG. 2, the battery 200 is substantially rectangular, adapted for mounting in the mounting slot 1011. The battery 200 defines a socket 201 on the front side of the battery 200.

The power adaptor 300 is substantially rectangular, and substantially same in shape and size as the battery. The power adaptor 300 defines a socket 301 on the front side of the power adaptor 300, and includes a power source interface 302 disposed on the rear side of the power adaptor 300.

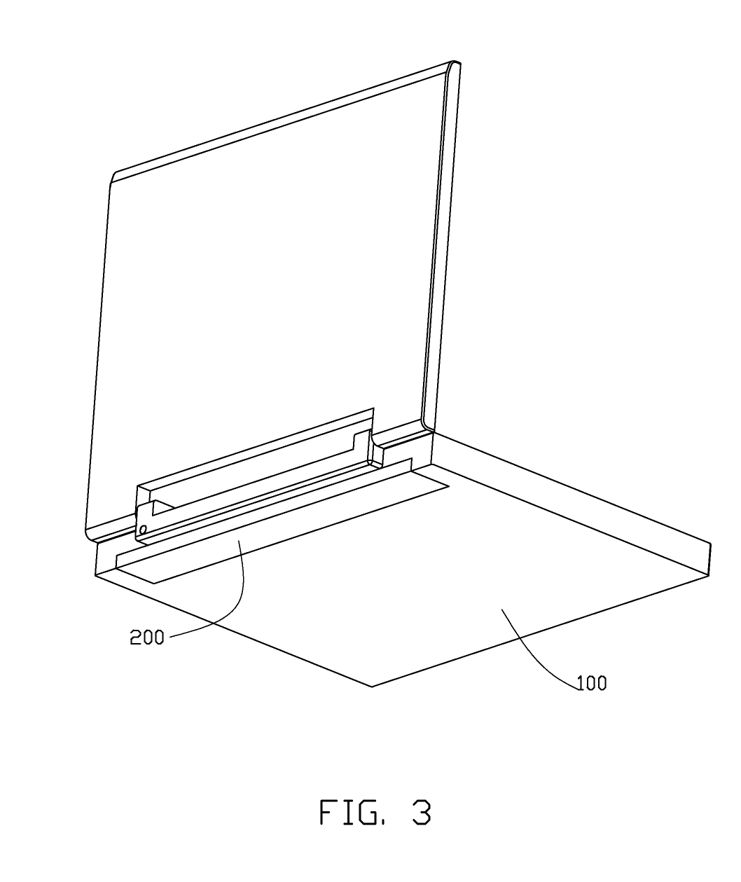

Referring to FIG. 3, powering the main body 100 with the battery requires that the battery 200 be mounted in the mounting slot 1011 of the main body 100, with the connector 1012 of the main body 100 inserted in the socket 201 of the battery 200 to achieve an electrical connection.

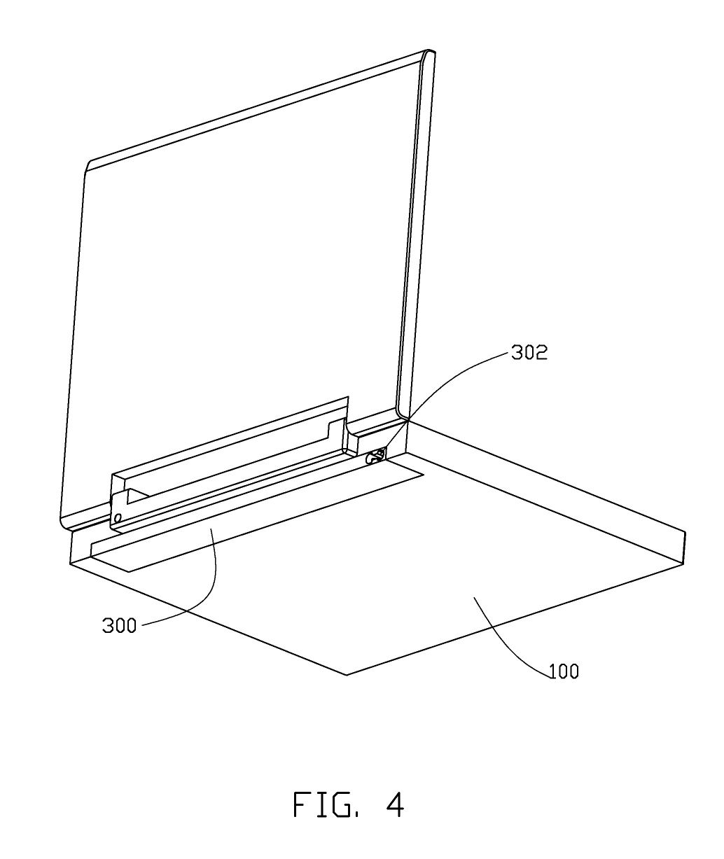

Referring to FIG. 4, to power the main body 100 from an alternating current (AC) power source, the power adaptor 300 is mounted in the mounting slot 1011 of the main body 100 in place of the battery 200, with the connector 1012 of the main body 100 inserted in the socket 301 of the power adaptor 300 as the electrical connection. A power cable or cord (not shown) is used to electrically connect the AC power source and the power source interface 302 of the power adaptor 300. The power adaptor 300 converts the AC voltage into a direct current (DC) voltage.

It is believed that the present embodiment and its advantages will be understood from the foregoing description, and it will be apparent that various changes may be made thereto without departing from the spirit and scope of the description or sacrificing all of its material advantages, the examples hereinbefore described merely being exemplary embodiments.

What is claimed is:

1. A notebook computer comprising:
a main body defining a mounting slot;
a battery; and
a power adaptor substantially the same as the battery in shape and size;
wherein the battery and power adaptor are selectively mounted in the mounting slot of the main body, thereby being electrically connected to the main body, the main body is powered by the battery, in response to the battery being mounted in the mounting slot; the main body is powered by an alternating current (AC) power source through the power adaptor, in response to the power adaptor being mounted in the mounting slot.

2. The notebook computer of claim 1, wherein the main body comprises a connector exposed through a side bounding the mounting slot of the main body, the power adaptor defines a socket directly connected to the connector of the main body in response to the power adaptor being mounted in the mounting slot of the main body.

3. The notebook computer of claim 1, wherein the main body comprises a connector exposed through a side bounding the mounting slot of the main body, the battery defines a socket directly connected to the connector of the main body in response to the battery being mounted in the mounting slot of the main body.

4. The notebook computer of claim 1, wherein the power adaptor comprises a power source interface to be connected to the AC power source.

5. The notebook computer of claim 1, wherein the battery and the power adaptor are rectangular in shape.

6. A notebook computer comprising:
a main body defining a mounting slot; and
a power adaptor mounted in the mounting slot, thereby being electrically connected to the main body, to power the main body by an alternating current power source through the power adaptor.

7. The notebook computer of claim 6, wherein the main body comprises a connector exposed through a side bounding the mounting slot of the main body, the power adaptor defines a socket connected to the connector of the main body.

8. The notebook computer of claim 6, wherein the power adaptor comprises a power source interface to be connected to the alternating current power source.
